(19) United States
(12) Patent Application Publication
(10) Pub. No.: US 2015/0010036 A1
(43) Pub. Date: Jan. 8, 2015

(54) OPTICAL AMPLIFIER SYSTEM AND PULSED LASER USING A REDUCED AMOUNT OF ENERGY PER PULSE

(71) Applicant: EOLITE SYSTEMS, PESSAC (FR)

(72) Inventor: Francois Salin, Gradignan (FR)

(73) Assignee: EOLITE SYSTEMS, PESSAC (FR)

(21) Appl. No.: 14/377,490

(22) PCT Filed: Feb. 8, 2013
(86) PCT No.: PCT/FR2013/050271

§ 371 Date: Aug. 7, 2014

(30) Foreign Application Priority Data
Feb. 9, 2012 (FR) 1251214

(51) Int. Cl. H01S 5/068; H01S 5/20; H01S 5/10

(52) U.S. Cl. CPC H01S 5/068; H01S 5/10; H01S 5/20
USPC 372/98; 359/337.1

(57) ABSTRACT

The invention relates to an optical amplifier system for amplifying laser pulses, including a solid amplifying medium capable of receiving a beam of laser pulses to be amplified and generating a beam of amplified laser pulses, and a means of reducing the energy stored in said optical amplifying medium by means of optical pumping. According to the invention, said reducing means includes a continuous resonant cavity and a first optical separation means capable of sepaarating continuous resonant cavity into a common portion and a low arm, the common portion including an optical amplifying medium and the loss arm inlcuding an optical loss means, said optical separation means being capable of selectively directing a beam of pulses outside the optical path of said loss arm of the continuous resonant cavity, and of directing a continuous bean toward said loss arm of the continuous resonant cavity.

The present invention concerns the operation of lasers and optical amplifiers in pulsed mode for amplification of high power, high energy and high speed pulses. More specifically, the invention concerns an amplifier or a pulsed laser in which the maximum energy stored and/or produced is limited to a predetermined value, regardless of pulse speed variations. The invention preferably concerns a rod type fiber optical amplifier or laser.

There are many ways to produce pulsed radiation from a laser system. It is easy to distinguish the oscillators which produce periodic pulse trains directly and the amplifiers which augment the energy of pulses produced elsewhere.

Pulsed laser systems are widely used in industry in particular to machine, mark, engrave and bore various materials. In all of these applications, the user wishes to trigger the emission of pulses only when the piece to be machined is centered on the laser bundle. The system thus alternates between stop phases and emission phases during which a pulse or a series of pulses is emitted at a high rate. These phases of emission and of stoppage alternate at scales which can range from several microseconds to several minutes and with extremely variably frequencies.

A problem appears in all of the solid state laser systems during these stop and go phases because of the limited storage capacity for energy with the gain mediums used in these lasers. Most modern solid state lasers use continuous laser diodes as a pumping source. In the case of an oscillator, a laser material is inserted in a resonator and receives permanent radiation from one or more pumping laser diodes. The resonator also contains an optic switch capable of blocking or allowing passage of the laser emission. The switch is kept in a blocking position during a duration T1 in order to let the laser material charge with energy. At the end of this period, the switch is opened abruptly and a short laser pulse is emitted. The energy from the laser pulse emitted is proportional to the energy stored in the laser medium. The pulsed lasers are designed so that the energy stored during a pumping period and thus emitted by the pulse cannot exceed the damage threshold of the laser components.

A solid state laser generally has a fluorescence time, corresponding approximately to the time during which it is capable of storing energy, which is much longer than the time that elapsed between the emissions of two stationary successive pulses. For example, the fluorescence time of the neodymium ion in YAG is approximately 200 μs and that of the ytterbium ion in glass is approximately 1200 μs. These durations are much longer than the typical periods of the pulsed lasers which generally operate at rates from 10 kHz to multiple MHz. According to the repetition frequency, the duration T1 between two successive pulses of a pulse train laser is thus generally lower than 100 μs and can be lower than 1 μs.

When the user stops the laser emission, the switch remains in the blocking position. However, with the pump operating in continuous mode, it continues to charge the gain medium with energy. When the user decides to use the laser, it unblocks the switch and the laser emits a pulse with energy that can be much greater than that in the stationary mode. This giant first pulse phenomenon in solid state lasers is well known and many solutions have been proposed to try to combat it.

On the other hand, the user may wish to modify the frequency of the pulses in real time while maintaining a constant pulsed energy. This is especially the case when the triggering of the pulses should be synchronous with displacement of a piece. During the acceleration and deceleration phases of the piece, the frequency of the pulses should vary by a factor that can exceed ten. The storage time then varies permanently and it becomes impossible to keep a constant energy in the gain medium.

In U.S. Pat. No. 5,226,051, a solid state laser is proposed in which the pumping power is reduced when the duration between two successive pulses exceeds a certain cap value. In this way the energy stored in the laser medium is limited to the value corresponding to the stationary mode. This solution can apply only if the laser diodes can be modulated rapidly, which is not the case is most power diodes used for pumping solid state lasers. In addition, rapidly modulating the power emitted by a laser diode greatly reduces its service life and causes a variation in its emission wavelength, introducing fluctuations in the laser pulses. Lastly, this system operates only at a predefined rate.

U.S. Pat. No. 6,038,241 describes a solid state laser including an optic switch whose losses are controlled electronically in order to maintain an energy level (given by the quantity of excited population) in the gain medium near the stationary level. The excess energy is evacuated in the form of a continuous bundle having the same geometric characteristics as the pulsed laser bundle. This system has several drawbacks: it requires complex control electronics, it requires advance knowledge of the frequency of the pulses after interruption by the user, and it produces a continuous laser bundle of the same direction, same wavelength and same polarization as the main pulsed bundle. The continuous laser bundle can damage or distort the piece to be handled.

Patent document WO 2004/095657 describes a similar system used to maintain a constant thermal lens in a solid state laser.

U.S. Pat. No. 6,009,110 gives another example of an electronic system based on a similar mode of operation but adapted to lasers with wavelengths converted intra-cavity.

Patent document WO 2008/060407 describes a regenerative amplifier integrating an electro-optic polarization modification system and a complex electronic system in order to eliminate the first pulse (extra strength) after an interruption of the emission of laser pulses. This regenerative amplifier comprises a laser cavity and an electro-optic modulator which makes it possible to inject into the cavity a pulse generated externally then to eject the amplified pulse after a great number of passages in the cavity.

Document WO 2005/013445 describes an erbium-doped fiber optical amplifier for amplifying pulses at a first wavelength, with the amplifier being arranged within a secondary resonator that emits pulses at another wavelength when the amplifier gain medium reaches a threshold.

These various systems can operate with triggered lasers or regenerative amplifiers but are not appropriate in the case of a single or double passage amplifier. Prior devices use complex control modes with an optic switch placed in the resonator. They can also cause the emission of a continuous laser bundle collinear with the bundle of laser pulses which may not be acceptable to the user.

A first purpose of the invention is to protect the components of the fiber optical amplifier system vis-à-vis too much energy stored in the gain medium. With this purpose in mind, the invention seeks to limit the energy stored in a fiber optic gain medium, regardless of the pumping power, regardless of the repetition frequency and regardless of the duration of interruption between successive pulse trains. The invention thus seeks to limit the energy of a first laser pulse after an interruption in the emission of a laser pulse train.

A second purpose of the invention is to ensure that the energy of the pulses delivered is constant regardless of the frequency of the pulses, the duration of interruption between two successive pulses and/or the pumping power.

The purpose of the present invention is to remedy the drawbacks of the prior techniques and concerns more specifically an optical amplifier system for amplification of high power, high energy and high speed laser pulses, with such optical amplifier system comprising a solid state optic gain medium, and with such optic gain medium being able to receive a bundle of laser pulses to amplify and to generate a bundle of amplified laser pulses, with the rate of the pulses being between 1 kHz and several hundred kHz, and the means to limit the energy stored by optic pumping in such optic gain medium. According to the invention, such means of limitation comprise a continuous resonating cavity arranged around such optic gain medium and the first optic means of separation arranged in such continuous resonating cavity, with such first optic means of separation being able to separate such continuous resonating cavity into a common part and a branch of losses, with the common part comprising the optic gain medium and the branch of losses comprising the means of optic losses, with such first optic means of separation being able to direct a bundle of pulses selectively outside the optic trajectory of such branch of losses of the continuous resonating cavity and to direct a continuous bundle toward such branch of losses of the continuous resonating cavity so as to generate a continuous laser bundle in such continuous resonating cavity when the gain of the gain medium is greater than or equal to a predetermined threshold equal to the optic losses and to generate a bundle of amplified pulses limited in energy by pulse, with such gain medium requiring a propagation axis unique to the bundle of amplified pulses and to the continuous laser bundle.

According to a particular aspect of the invention, the optical amplifier system of the invention also comprises a second optic means of separation able to separate spatially such bundle of amplified pulses and the continuous laser bundle, the optic gain medium being laid between the first optic means of separation and the second optic means of separation, so as to generate a bundle of amplified pulses limited in energy following a first direction and to generate a continuous laser bundle following another direction.

According to a preferred form of embodiment, such optic gain medium comprises a fiber optic or a fiber optic rod, the trajectory of the continuous laser bundle and of the bundle of pulses being collinear in the gain medium, and such fiber optic or such fiber optic rod having a bandwidth of amplification or a gain of amplification of spectral width greater than or equal to 1 nm.

According to particular aspects, such first optic means of separation and/or second optic means of separation comprise at least a dichroic filter able to separate both the bundle of laser pulses at a wavelength λ₁ and the continuous laser bundle at a wavelength λ₂.

According to another particular aspect, the second optic means of separation comprise a polarization filter and/or such first optic means of separation comprise a polarization filter, with such polarization filter being able to separate the bundle of laser pulses according to a first polarization and the continuous laser bundle according to a second polarization distinct from the first polarization.

According to a preferred aspect, the optic losses induced by such means of optic losses are adjustable so as to adjust the threshold of the continuous resonating cavity.

The invention also concerns a laser triggered with high power, high energy and high speed triggered pulses comprising a solid state optic gain medium arranged in a first resonating cavity, means of optic triggering arranged in such first resonating cavity, so as to trigger the emission of a bundle of high speed laser pulses in such first resonating cavity, with the laser pulse rate being between 1 kHz and several hundred KHz and means of limitation of the energy stored by optic pumping in such optic gain medium. According to the invention, such laser comprises a second continuous resonating cavity, with the first resonating cavity and the second continuous resonating cavity having a common part comprising the optic gain medium and the means of optic triggering, with the first resonating cavity having at least a first branch separate from such common part, and the second resonating cavity having at least a second branch of losses separate from such common part, such second branch of losses comprising means of optic losses and the first optic means of separation being arranged in such first and second resonating cavity so as to separate the common part respectively of the first branch and the second branch of losses, such first optic means of separation being able to direct a bundle of laser pulses toward the first branch of the first resonating cavity and to direct a continuous laser bundle toward the second branch of losses of the second continuous resonating cavity.

According to a specific form of embodiment, such means of optic triggering comprise an acousto-optic modulator (polarizing or non polarizing) or an electro-optic modulator.

According to a preferred form of embodiment, such optic gain medium comprises a fiber optic or a fiber optic rod, such fiber optic or such fiber optic rod having a bandwidth of amplification and/or a gain of amplification with a spectral width greater than or equal to 1 nm.

According to a particular aspect of the pulsed laser, the second optic means of separation comprise a dichroic filter and/or such first optic means of separation comprise a dichroic filter, such dichroic filter being able to separate the bundle of laser pulses at a wavelength λ₁ and the continuous laser bundle at a wavelength λ₂.

According to another form of embodiment, the second optic means of separation comprise a polarization filter and/or such first optic means of separation comprise a polarization filter, such polarization filter being able to separate the bundle of laser pulses according to a first polarization and the continuous laser bundle according to a second polarization distinct from the first polarization.

According to different aspects of the invention, such means of optic triggering comprise a type Q-switch passive trigger, or a non polarizing acousto-optic modulator or an acousto-optic modulator.

According to a particular aspect, such means of loss are adjustable so as to adjust the threshold of the continuous resonating cavity.

According to another particular aspect, the second optic means of separation comprise a non-linear crystal able to produce a wave at a different frequency from the fundamental wave with an output dependent on the incident wavelength and/or the incident polarization and/or the incident peak power.

The invention also concerns a triggered pulsed laser and an optical amplifier using an energy limiter according to one of the modes of embodiment described, with the system comprising two gain mediums separated by at least one optic component closing the first resonating cavity of the triggered pulsed laser, in which the continuous laser bundle produced by the second continuous resonating cavity traverses the second gain medium.

The invention also concerns a process of high power, high energy and high speed laser pulse amplification, with the process comprising the following stages:
Optic pumping of a solid state gain medium;
Generation of a bundle of laser pulses to be amplified at a rate of between 1 kHz and several hundred kHz;
Addressing of the bundle of laser pulses to be amplified in the direction of a solid state gain medium
Amplification of the bundle of laser pulses by single or double passage in the solid state gain medium so as to generate a bundle of amplified laser pulses.

According to the invention, the process comprises a state of limitation of energy stored by optic pumping in such optic gain medium, with such limitation stage comprising the following stage:
formation of a continuous resonant cavity comprising such solid state gain medium to generate a continuous bundle in such continuous resonant cavity when the gain of the gain medium is greater than or equal to a preset threshold equal to the optic losses and to generate a bundle of amplified pulses limited in pulsed energy.

The invention will have a particularly advantageous application in a fiber optic pulsed laser.

The present invention also concerns the characteristics brought forth in the description to follow and that should be considered in isolation or according to all of their technically possible combinations.

The invention will be better understood and other purposes, details, characteristics and advantages of the invention will appear more clearly in the description of one or more particular forms of embodiment of the invention given solely for illustrative and non-limiting purposes in reference to the attached drawings. In these drawings:

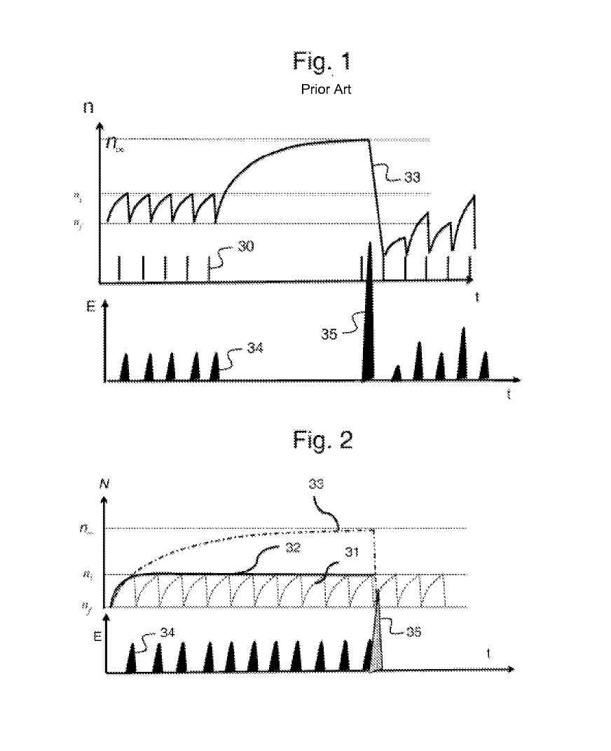

FIG. 1 is a schematic representation of the evolution of the population of excited ions (curve from above) as a function of the time and of the pulses of an external trigger (pulses from the medium), and respectively the energy of the laser pulses (pulses from below) in a pulsed laser from prior art;

FIG. 2 is a schematic representation of the principle of the limitation of the excited population in an optic gain medium or pulsed laser;

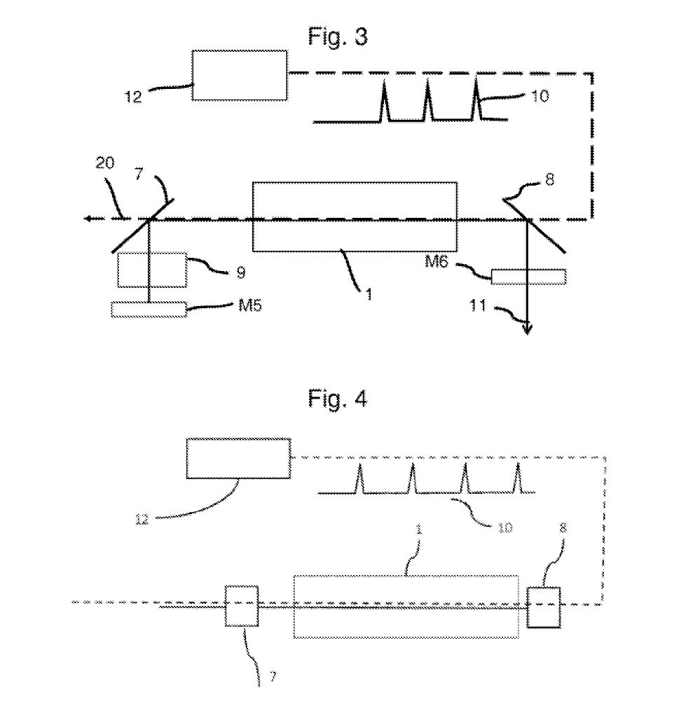

FIG. 3 is a schematic representation of an optical amplifier with a single passage integrating an energy limiter according to a first form of embodiment;

FIG. 4 is a schematic representation of an optical amplifier with a single passage integrating an energy limiter according to another form of embodiment;

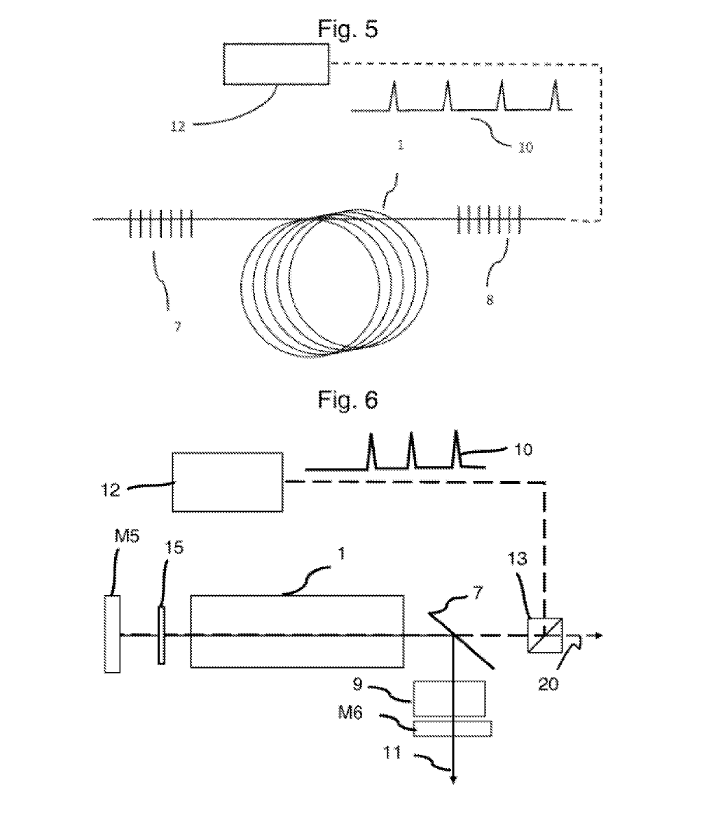

FIG. 5 is a schematic representation of a fiber optical amplifier according to a variant of the form of embodiment of FIG. 4;

FIG. 6 is a schematic representation of a double passage optical amplifier integrating an energy limiter according to a second form of embodiment;

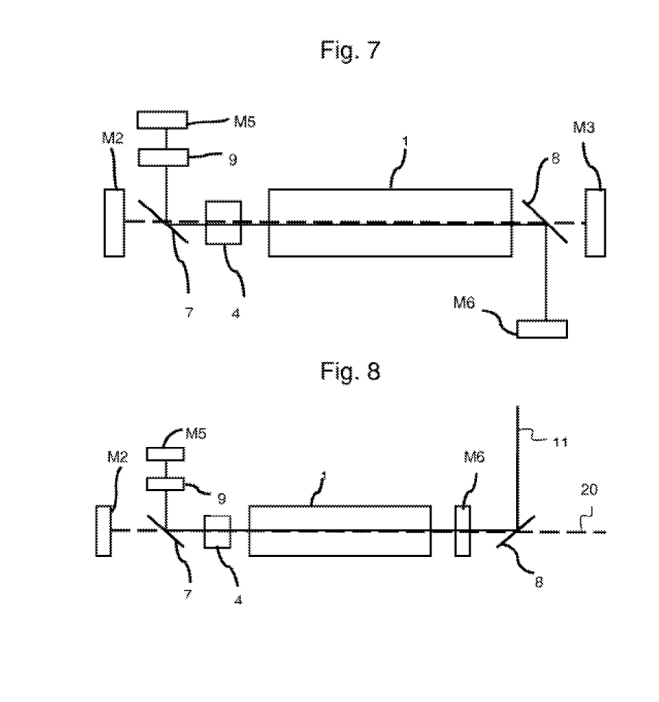

FIG. 7 is a schematic representation of a pulsed laser comprising an energy limiter with interconnected cavities according to a third form of embodiment of the invention;

FIG. 8 is a schematic representation of a pulsed laser comprising an energy limiter with interconnected cavities according to a variant of FIG. 7;

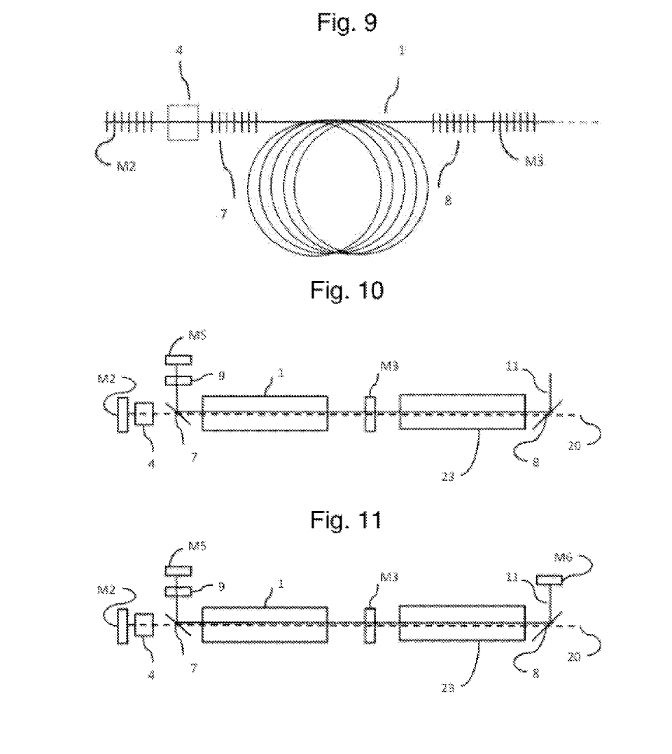

FIG. 9 is a schematic representation of a pulsed laser to fiber optic according to a variant of FIG. 8;

FIG. 10 is a schematic representation of a system integrating multiple optic gain mediums according to another form of embodiment;

FIG. 11 is a schematic representation of a system integrating multiple optic gain mediums according to a variant of FIG. 10;

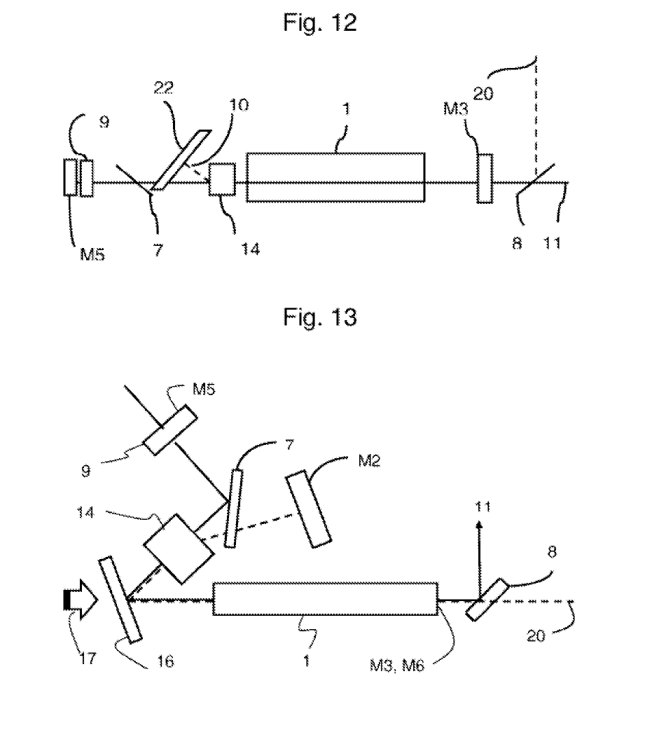

FIG. 12 is a schematic representation of a pulsed laser limited in energy according to another form of embodiment using an acousto-optic modulator;

FIG. 13 is a schematic representation of a pulsed laser limited in energy according to a preferred form of embodiment of the invention;

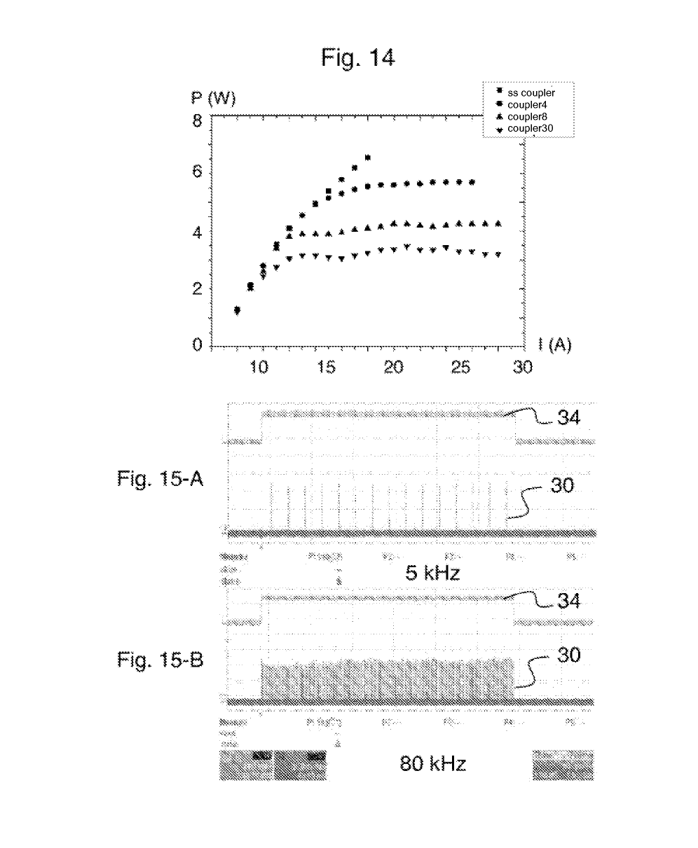

FIG. 14 represents a set of measures of mean power produced by the laser according to a form of embodiment of the invention, the mean power being a function of the current applied to the pumping diode and of the level of the losses induced;

FIGS. 15A and 15B represent a laser pulse train with different operating rates for the laser.

The invention relies on the use of a device making it possible to eliminate an “overflow” of energy as it is stored in a solid state gain medium during the continuous optic pumping.

More precisely, the invention concerns a system, preferably passive, making it possible to limit to an adjustable value the energy of the pulses produced by a triggered oscillator or an amplifier. The device can be used to eliminate the first pulse of a pulse train in a pulsed system, to produce constant pulses of energy at randomly variable frequencies or to limit the outgoing energy produced from an optical amplifier and avoid any damage in the final application.

To simplify the explanation, we will first describe the operation of the device in an amplifier. Operation in a laser resonating cavity is described later.

FIG. 1 is a schematic representation of the evolution as a function of the population time of excited ions (curve 33) in an optic gain medium triggered at instants distributed as a function of the time (triggering pulses 30). It is known that the energy E of a pulse produced by a laser oscillator pulsed by triggering is proportional to the energy stored in the gain medium before the optic switch is triggered. When the triggering is done periodically, a stationary state is reached as shown in FIG. 1 for the first five pulses. The population excited in the gain medium oscillates between the values n_{f} and nᵢ. The energy E of the pulses 34 is proportional to the difference nᵢ−n_{f}. After a series of pulses, we assume that the user stops the emission of pulses during a long time before a standard operating period, and the excited population increases to the value n∞ where it saturates. When triggering is resumed, the first pulse emitted 35 has a much greater energy because of this very large excited population stored in the laser medium. Likewise, if the period between successive triggering pulses 30 varies, the energy E of the pulses emitted 34 varies proportionally. The high energy pulses emitted 34 risk damaging the gain medium, especially with an amplifying fiber optic or a fiber optic rod.

The purpose of the invention is to maintain a maximum excited population equal to a predefined level lower than the maximum level n∞. FIG. 2 explains the principle used in the invention. The mode of operation of a pulsed laser according to the prior art is represented by the curves 31 and 33 and the emitted pulse 35. At a triggering rate, the population of excited ions oscillates between the values n_{f} and nᵢ (curve 31). If the triggering rate decreases, the pumping time increases and the excited population increases to the saturation value of the medium (curve 33). This risks triggering the emission of an extra-strength pulse 35. We want to limit the level of the excited population to a predefined value (as shown on curve 32) regardless of the rate of the laser. In this case, the energy of the pulses emitted 34 is limited by this maximum level of excited population (defined by curve 32). To obtain this limitation effect, we are using a continuous effect laser in a laser cavity interconnected in the principal cavity. A continuous laser stabilizes very quickly around an operation for which the gain in the cavity is very precisely equal to the losses of the latter. This point of operation corresponds to the level of population necessary to reach the threshold since the gain is directly proportional to the excited population. By charging the level of the losses in a continuous laser it is possible to then adjust the excited population of the laser medium and adjust the level of limitation nᵢ for the amplification of the pulses.

We will now describe the use of this principle in a single passage amplifier, shown schematically in FIG. 3. We are considering an optic gain medium 1 pumped continuously. In FIG. 3 and following, the continuous pumping source is not shown. The population of excited ions increases in the gain medium 1 along with the duration of pumping up to the saturation value. When a laser pulse is incident on the gain medium 1, it is amplified by stimulated emission and produces a decrease in the excited population in the gain medium. The energy of the amplified pulse is proportional to the energy stored in the medium. As explained in connection with FIG. 1, in a laser triggered according to the prior art, when the pumping time varies, the energy of the amplified pulses varies proportionally. The energy of the amplified pulses can exceed the amplifier damage threshold. The excess energy of the amplified pulses can also be a problem for the user wanting a constant energy regardless of the repetition rate of the incident pulses. The present invention proposes a first specific form of embodiment shown in FIG. 3. A laser oscillator 12 is used to produce the laser pulses to be amplified 10. The time separating two pulses 10 can vary in large proportions but the user wants to obtain a constant energy out of the amplification chain. The pulses 10 to be amplified are incident on an optic gain medium 1. A filter 7 and a filter 8 are positioned on each side of the gain medium 1. The filters 7 and 8 are advantageously able to filter the polarization or the wavelength of an optic bundle. A laser cavity or resonator C2 (shown in a straight line) is formed by two mirrors M5 and M6, at least one of which is partially reflecting. The optic gain medium 1 is located inside known resonator C2. A system of adjustable losses 9 is inserted in this resonator C2 but not on the optic trajectory of the pulses to be amplified 10 or of the amplified pulses 20. This system of adjustable losses can, for example, be composed of a quarter wave blade 9 associated with a polarizer which may or may not be distinct from the filter 7. An adjustment is made to the losses introduced by this unit by adjusting the angle formed by the direction of polarization defined by the polarizer and the direction of the slow axis of the quarter wave blade. The rotation of the quarter wave blade can advantageously be motorized. In another embodiment the system of losses can also be composed of a blade in a transparent material in which the angle between the surface and the axis of the bundle can be modified. The reflectivity of this blade varies with the incidence, so it is possible to regulate the losses from the cavity C2. The blade can be treated with one or more layers to accentuate this variable reflectivity effect.

When the pumping time of the amplifier 1 increases, the gain of this amplifier 1 increases until the gain of the amplifier is equal to the losses in the cavity C2. A continuous laser oscillation is created then between the mirrors M5 and M6 and maintains the excited population at the value corresponding to the oscillation threshold of the continuous laser cavity C2. When a pulse emitted by the oscillator 12 arrives in the amplifier 1, it finds that the excited population corresponding to this threshold and its energy after amplification cannot exceed a cap value set by the losses of the device 9.

In a preferred form of embodiment, the optic gain medium 1 is a gain medium having a wide gain bandwidth, meaning able to amplify, possible with a different gain, a bundle of pulses to a first wavelength λ₁ and a continuous laser bundle to a second different wavelength λ₂ of λ₁. Preferably, the optic gain medium 1 is a fiber optic or a fiber optic rod having a wide gain spectral band (preferably greater than or equal to 1 nm). The fiber optic or fiber optic rod gain medium generally has a weak transverse spatial reach. The bundle of pulses and the continuous laser bundle are then collinear in the fiber optic or to fiber optic rod gain medium. The filters 7 and 8 are advantageously wavelength filters, for example able to transmit a bundle of pulses at wavelength λ₁ and to reflect a continuous laser bundle at wavelength λ₂, the wavelengths λ₁ and λ₂ being located in the gain band of the gain medium. In this particular case, the gain medium 1 cannot retain the polarization and the bundle to be amplified 10 does not need to be polarized.

In another form of embodiment shown in FIG. 4, the mirrors M5 and M6 are incorporated in the filters 7 and 8. These filters 7 and 8 then operate at normal incidence. At least one of the mirrors M5, M6 should have a reflectivity lower than 1. Each of these filters 7, 8 can be, for example, composed of a massive Bragg network which reflects the light at the wavelength λ₂ and transmits any other wavelength, in particular λ₁. The two continuous and pulsed bundles are then emitted according to the same axis. They are then separated by another spectral filter 22 which can be a simple dichroic mirror or another massive Bragg network working outside the nul incidence or else a module of harmonic generation with a narrower spectral acceptance than the separation between λ₁ and _{λ2}. The regulation of losses in the cavity C2 can, for example, be adjusted by changing the temperature of one of the Bragg networks 7, 8. Such a variation of the temperature will slightly shift spectrally the reflectivity curve of said network. The wavelengths corresponding to the maximum reflection of the two networks M5 and M6 no longer correspond exactly, causing losses in the cavity C2. The greater the shift the greater the losses.

In a specific form of embodiment shown in FIG. 5, the filters 7 and 8 can be integrated or welded to the amplifying fiber optic 1 by taking the form of, for example fiber Bragg networks, at least one of which has a reflectivity lower than 100%. The reflecting wavelength of the networks 7 and 8 is then chosen for being different from the wavelength of the pulses to be amplified. These two Bragg networks thus form a cavity C2 for which the losses are adjusted, for example, by adjusting the temperature of one of the two Bragg fiber networks. This cavity C2 can thus emit a continuous radiation at the wavelength λ₂ as soon as the gain in the gain medium 1 exceeds the losses introduced by the two Bragg networks 7, 8.

In another form of embodiment, shown in FIG. 6, the optic gain medium 1 is used in double passage. A polarizer 13 is placed on the optical path between the oscillator 12 and the optic gain medium 1. The polarizer 13 is, for example, a polarization separation cube. A quarter wave blade 15 and a mirror M5 are placed after the gain medium 1. The pulse train to be amplified 10 makes a first passage in the amplifier 1 according to a polarization and makes a second passage according to the same propagation axis but in the opposite direction and with a perpendicular polarization. The polarizer 13 separates the incident bundle of pulses to be amplified 10 and the amplified bundle of pulses 20. As in the form of embodiment of FIG. 3, a resonating cavity C2 has a mirror M5 and a mirror M6 for ends and comprises the wide gain bandwidth gain medium 1. The resonating cavity C2 also comprises a system of optic losses 9. A filter 7 is arranged in the resonating cavity C2 between gain medium 1 and the system of optic losses 9 so that the system of optic losses 9 is not on the optic trajectory of the pulses to be amplified 10 or of the amplified pulses 20. The filter 7 is a filter able to separate a first wavelength λ₁ and a second wavelength λ₂. The filter 7 thus separates the resonating cavity C2 into a common part and a branch comprising the system of losses. The common part comprises the gain medium 1. In the common part, the optic trajectory of the continuous laser bundle and of the pulses is collinear. The mirror M5 is able to reflect the two continuous and pulsed bundles at wavelengths λ₁ and λ₂. Only a continuous laser bundle 11 is propagated in the branch of losses of the resonating cavity C2. Preferably, an adjustable system of optic losses 9 is used. It can be composed, for example, of a blade made of glass or any other transparent material for which the angle to the axis of the continuous laser bundle 11 can be varied. By adjusting the level of losses of the system of optic losses 9, it is possible to regulate the resonating cavity C2 to limit the energy stored in the gain medium 1 without affecting the propagation of the bundle of pulses to be amplified.

On can easily extend use of the device from the invention to a short pulsed laser. The problem is similar. To do this we propose interconnecting two laser resonators sharing the same gain medium 1. FIG. 7 shows a functional diagram of another form of embodiment of the invention in a short pulsed laser. The optic gain medium 1 is surrounded by two mirrors M2 and M3 forming the ends of a first resonating cavity C1 or first laser cavity (shown by a broken line). One of the two mirrors (M2 or M3) is partially reflecting. The first resonating cavity C1 further comprises an optic switch 4, which can be an acousto-optic type switch able to modify the direction of an optic bundle or an electro-optic switch able to modify the polarization of an optic bundle. The optic switch 4 remains in a fixed state during the entire pumping period during which we would like to limit the energy. According to the invention we will build a second resonating cavity C2 (shown by a straight line) closed by two end mirrors M5 and M6, at least one of which is semi-reflecting so as to extract the continuous laser bundle. The two resonant cavities C1 and C2 share the same optic gain medium 1. A system of optic losses 9 is arranged in a separate branch switch the second cavity C2 that is not part of the first cavity C1. A filter 7 separates resonating cavity C2 in a common part comprising the gain medium 1 and a branch of losses comprising the system of optic losses 9. At the other end of the common part, a filter 8 separates a bundle at the wavelength λ₁ and a bundle at the wavelength λ₂. When the switch 4 blocks the emission of laser pulses in the first cavity C1, the excited population increases in the gain medium 1 until the gain in this medium is equal to the losses of the cavity C2. As soon as the gain of the gain medium 1 reaches the level of loss of the second cavity C2, the second cavity C2 automatically sets to continuous laser and any additional energy provided by the optic pumping system is put over onto the continuous laser bundle emitted by the second cavity C2. Advantageously an adjustable loss system 9 is used in the second cavity C2, to regulate the level of loss and thus the maximum level of the excited population in the gain medium 1. The adjustable losses system can be composed of a polarizer associated with a quarter wave blade placed between the mirror M5 and the polarizer or of a polarizer and of a half-wave blade placed between the filter 7 and the polarizer or of a simple glass blade with a variable incidence.

As in the form of embodiment described in connection with FIG. 3, the filters 7 and 8 are preferably filters with a wavelength able to separate a bundle of pulses at a first wavelength λ₁ and a continuous laser bundle at a second different wavelength λ₂. The optic gain medium 1 is able to amplify, possibly with a different gain, a bundle of pulses at the first wavelength λ₁ and a continuous laser bundle at the second different wavelength λ₂. The optic gain medium 1 is preferably a fiber optic or a fiber optic rod having a wide gain bandwidth (preferably greater than or equal to 1 nm).

Many variants are possible that have various advantages or drawbacks. In particular there are components 7 and/or 8 that make it possible to create two resonant cavities C1 and C2, at least one physical property of which differs, without introducing excessive losses on the cavity C1. In a fiber optic or fiber optic rod gain medium, the optic components 7 and/or 8 also ensure that the optical path of the bundle of pulses and respectively the optical path of the continuous laser bundle are collinear in the optic gain medium 1 common to the two resonant cavities C1 and C2.

According to a first variant (cf. FIG. 8), the component 8 is placed outside of the resonant cavities C1 and C2, the mirror M6 forming an outlet end common to the resonant cavities C1 and C2. The component 8 makes it possible to separate the direction of emission of the continuous laser bundle 11 and the direction of emission of the bundle of amplified pulses 20, which is the main bundle of interest for the user. The continuous laser bundle 11 is thus emitted in a different direction from the bundle of laser pulses 20. The radiation of the continuous laser bundle 11 can reach a very high level of power but can be trapped to avoid affecting the use of the bundle of pulses 20. Note that the component 8 can function in reflection, in transmission or in absorption.

We propose a specific mode of operation of the energy limiter which makes it possible to ensure that the pulses emitted by the laser have a maximum energy set by the user and also to eliminate the parasite continuous bundle without creating losses on the principal bundle of pulses.

To obtain two cavities C1, C2 interconnected but independent, we propose using filters with a wavelength 7 and 8 able to separate a bundle with a first wavelength λ₁ and a bundle with a different wavelength λ₂. In this case the first resonating cavity C1 lases on a first wavelength λ₁ transmitted by the filters 7 and 8 and the second resonating cavity C2 lases on a different wavelength λ₂, reflected by the filters 7 and 8. The filter with wavelength 7 can be placed anywhere between the gain medium 1 and the cavity bottom mirror M2.

The main bundle of pulses oscillates between the mirrors M2 and M3 and can be pulsed at a variable rate by the switch 4. The continuous laser bundle oscillates between the mirrors M5 and M3.

In a particular mode of operation, the optic gain medium 1 is pumped continuously by one or more laser diodes. The switch 4 is used to block the emission of laser pulses between the mirrors M2 and M3. The excited population stored in the medium 1 increases progressively. Once the population reaches the level corresponding to the threshold of the laser effect in the second resonating cavity C2 formed by the mirrors M5 and M6, a continuous laser bundle is emitted. The excited population is then constantly maintained at this value by the continuous laser effect. Once the user triggers the cavity C1 by moving the switch 4, a laser pulse with the wavelength λ₁ forms in the cavity C1 and is emitted by the laser C1. The wavelength filter 8 makes it possible to separate the bundle of pulses at the wavelength λ₁ and rejects the continuous laser bundle at the wavelength λ₂ outside the trajectory of the main bundle of pulses.

In an alternate or supplementary manner, it is possible to consider using polarization properties in the first resonating cavity C1 and/or in the second resonating cavity C2. The device then operates in the case of a polarized laser. On the separate part of the first cavity and/or of the second resonating cavity, it is possible to place a polarizing element allowing the two resonant cavities to function according to two polarization states (for example: horizontal polarization for the first resonating cavity C1 and vertical polarization for the second resonating cavity C2). The main bundle of pulses (broken line) is then polarized, for example, horizontally and the continuous laser bundle (straight line) is polarized vertically.

In addition, the device for regulating the level of limitation of the excited population can be composed of a quarter wave phase blade for which the orientation is regulated so that, when associated with a polarizer, the phase blade induces the necessary losses to set the maximum population level that the gain medium 1 can store. It is also possible to use a partially reflecting mirror M5 to adapt the level of losses roughly and use the phase blade device and polarizer to refine the adjustment.

In an alternative manner shown in FIG. 9, the filters 7 and/or 8 can be composed of fiber Bragg networks. The reflectors M2 and M3 forming the cavity C1 can also be either or both Bragg fibered networks. The cavity C1 is formed by the Bragg mirrors M2 and M3 and produces pulses from the switch 4. The cavity C2 formed by the networks 7 and 8 emits at a different wavelength a continuous radiation once the gain in the gain medium 1 exceeds a preset threshold.

In a particular configuration shown in FIG. 10 it is possible to use the object of the invention to limit the energy of the pulses produced in a system integrating multiple optic gain mediums. A standard case consists of using a first optic gain medium 1 in a laser cavity composed of the mirrors M2 and M3 to produce a generally pulsed radiation, followed by a second optic gain medium 23 to amplify this radiation. The energy limiter device is integrated into the first resonator forming a second cavity with the use of the mirrors M5 and M3 but the continuous radiation 11, produced by the cavity C2 when the energy stored in the first optic gain medium 1 exceeds the limit set by the user, is kept on a propagation axis common to that of the pulsed radiation to be amplified 20. To do this there should be no second filter 8 between the amplifier 1 and the amplifier 23. The continuous laser bundle 11 is thus incident on the second gain medium 23 and is amplified. It extracts part of the energy stored in this second gain medium 23, thereby limiting the energy of the amplified pulses in this second gain medium 23. A filter 8 can be introduced after the second gain medium 23 to separate the continuous radiation produced by the cavity C2 then amplified by the amplifier of the pulsed radiation produced by the cavity C1 and amplified by the amplifier.

In a first form of embodiment of FIG. 10 it is possible to use a mirror M3 common to the cavities C1 and C2.

In a second form of embodiment in FIG. 11, the mirror M3 reflects only the pulsed wave 20 and transmits the continuous wave 11. The cavity C2 is then formed with the use of the mirror M5 and of a mirror M6 positioned after the second gain medium 23 and separated from the radiation 20 by the filter 8. Here again the filter 8 and the mirror M6 can be replaced by a single element taking the form of, for example, a Bragg mirror or a dichroic mirror.

In a specific form of embodiment, the second filter 8 is composed of a non-linear crystal that can produce a harmonic radiation from a wave of fundamental frequency at the proper wavelength. The conversion result obtained in this crystal will be optimized in polarization, wavelength and peak power for the wave issued from the cavity C1 and will thus be much weaker for the wave issued from the cavity C2. This system makes no distinction between continuous and pulsed waves issued respectively from the cavities C2 and C1 directing it in different directions but by conversion result toward an wave of a different wavelength. In particular the non-linear crystal can be a crystal sized for the production of the second fundamental wave harmonics. This crystal can be, for example, a crystal of LBO, of KTP, of BBO or of LiNbO₃.

FIG. 12 proposes a specific form of embodiment in which the mirror M2 is replaced by a diffraction network 22 and the switch is an acousto-optic modulator 14. The diffraction network 22 has an angular acceptance lower than the angle of diffraction between two orders of the acousto-optic modulators. The main bundle of pulses 10 is then diffracted by the acousto-optic modulator 14 when the acousto-optic modulator is in pass position. The ends of the first resonating cavity C1 are the mirror M3 and the diffraction network 22. A bundle of pulsed laser pulses oscillates in the first resonating cavity C1. To block the first resonating cavity C1, the command signal of the acousto-optic modulator 14 is set at zero and the light is no longer diffracted. By placing a mirror M5 behind the diffraction network 22 a second resonating cavity C2 is formed with the mirror M5 and the mirror M3 as ends. When the acousto-optic modulator 14 is in block position, no laser pulse 10 can be amplified in the gain medium 1. When the pumping of the gain medium 1 is continued, a continuous laser bundle 11 can form in the second resonating cavity C2. The diffraction network 22 is chosen to be very selective angularly, so as to reflect a bundle diffracted by the acousto-optic modulator and so as to transmit a bundle transmitted by the acousto-optic modulator. In this form of embodiment, the acousto-optic modulator serves to direct the bundle of pulses in the first cavity C1 and the continuous laser bundle in the second cavity C2. In a similar manner to the previous modes of embodiment, the second resonating cavity C2 comprises a system of optic losses 9, preferably adjustable so as to adjust the threshold of the second laser cavity. A pair of filters 7 and 8 makes it possible to distinguish the continuous bundle 11 of the main bundle 10 or 20 by an optical characteristic (wavelength, polarization or any other characteristic) and to separate the outgoing continuous laser bundle 11 and the bundle of laser pulses 20. The filter 7 serves to require the cavity C2 to lase at the lambda wavelength 2 to be able to be rejected by the filter 8. Without it, C2 will lase at the peak of the gain and risk being transmitted by the filter 8. Likewise, if 7 and 8 are polarizers they should be oriented so that C1 and C2 lase on polarizations that are perpendicular to each other.

In a variant shown in FIG. 13, the diffraction network 22 is replaced by a mirror M2 with dimensions such that said mirror M2 is able to reflect a bundle diffracted by the acousto-optic modulator while allowing the continuous bundle 11 to pass to the side or the mirror M2 without being reflected.

The laser gain medium 1 is a medium crystalline or vitreous or fiber optic solid state. A particular case is the use of a rod type fiber. In certain modes of embodiment, the fiber is a fiber able to propagate a polarization without transforming it. In the case of an optical fiber, the outlet mirror M3, M6 common to the two resonant cavities C1 and C2 can be formed by polishing or cleaving the outlet face of the amplifier fiber 1 perpendicularly to the axis of the fiber (cf FIG. 8). The cavities C1 and C2 are then merged between the mirror M6 and the filter 7 and distinct between the filter 7 and the mirror M2 or between the filter 7 and the mirror M5.

FIG. 13 represents a preferred form of embodiment of the invention, in which a pulsed laser is made from a “rod type” fiber optic inserted in a first resonating cavity C1 formed by a mirror M2 at one end and the face M3 of the fiber optic polished perpendicularly to the bundle at the other end. The first resonating cavity C1 is triggered by an acousto-optic modulator 14 and comprises a filter 7 polarizer followed by a mirror M2. A second resonating cavity C2 has ends of the face M3 of the fiber optic and the glass blade 9 playing the role of partially reflecting reflector M5, with a reflection coefficient of around 4%. The gain medium 1 is pumped by a continuous laser diode. The emission rate is set at 10 kHz.

When the current I applied on the pumping diode is progressively augmented, the power P produced by the laser increases almost linearly (black squares on FIG. 14). The power curve stops at the value of 6.5 W corresponding to 650 μJ to 10 kHz which is the damage threshold of the fiber. It can be seen in this example that if the user continues to augment the pump current the laser will be damaged.

Then the device described in the invention is introduced by placing a filter in polarization between the acousto-optic modulator and the cavity bottom mirror and a reflector 9 on the bundle reflected by the polarizer. With a reflector 9 having a reflection coefficient equal to 4% the black circles on FIG. 14 are produced. It is observed that from a pump current I of 18 amperes, the power P of the laser saturates and the energy E of the pulses becomes independent of the pumping power. It is also noted that by changing the reflection coefficient to 8% (triangles pointed upward in FIG. 14) or 30% (triangles pointed downward in FIG. 14) it is possible to vary the saturation level. The explanation for this saturation is the threshold of the laser effect on the second resonating cavity C2. Beyond this threshold, all the supplementary pumping power is transferred onto the continuous bundle and no longer onto the laser pulse. There is thus a limitation on the energy of the pulses emitted.

An additional experiment was done by pumping the above laser with a very high power of 200 W. The device using a reflector of 4% was in place. We then varied the rate of the laser by changing the command signal of the acousto-optic modulator. In the absence of a limiter, such a laser should produce approximately 100 W independently of the rate or 50 mJ at 2 kHz and 10 mJ at 10 kHz. These values are theoretical as they are respectively 50 times and 10 times higher than the damage threshold of the fiber. In the absence of a limiter it is therefore not possible to maintain a pumping power of 200 W while modifying the rate in a range from 2 kHz to several hundred kHz. When the limiter is introduced the pulsed energy curves 34 from FIG. 15A are obtained for a rate of the triggered pulses 30 of 5 kHz and respectively the pulsed energy curves 34 of FIG. 15B for a rate of the triggered pulses 30 of 80 kHz. It is noted that regardless of the rate between 2 and 80 kHz the energy of the pulses (peak height) remains nearly constant. This proves that the invention limits the energy delivered by the laser regardless of the pumping time between two pulses.

The invention makes it possible to limit the energy accumulated in an optic gain medium intended to amplify optic pulses, preferably by single or double passage in the optic gain medium, and makes it possible to regulate the energy of the amplified pulses regardless of the frequency of the pulses and regardless of the duration of interruption between two successive pulse trains.

The invention device makes it possible to generate a bundle of laser pulses limited in energy to a preset level that is independent of the pulse repetition rate, by generating a continuous laser bundle emitted simultaneously with the laser pulses when the gain medium is greater than or equal to a preset threshold.

1. Optical amplifier system for the amplification of high power, high energy and high speed laser pulses (10), such optical amplifier system comprising:
A solid state optic gain medium (1), such optic gain medium (1) being able to receive a bundle of laser pulses to be amplified (10) and to generate a bundle of amplified laser pulses (20), with the rate of the laser pulses (10, 20) being between 1 kHz and several hundred kHz; and
means of limitation of the energy stored by optic pumping in such optic gain medium (1), characterized in that:
such means of limitation comprising a continuous resonating cavity (C2) arranged around said optic gain medium (1) and first optic means of separation (7, 14) arranged in such continuous resonating cavity (C2), such optic means of separation (7, 14) being able to separate such continuous resonating cavity (C2) in a common part and a branch of losses, the common part comprising the optic gain medium (1) and the branch of losses comprising the means of optic losses (9), such first optic means of separation (7, 14) being able to selectively direct a bundle of pulses outside of the optic trajectory of such branch of losses of the continuous resonating cavity (C2) and to direct a continuous bundle toward such branch of losses of the continuous resonating cavity (C2) so as to generate a continuous laser bundle (11) in such continuous resonating cavity (C2) when the gain of the gain medium (1) is greater than or equal to a predetermined threshold equal to the optic losses and to generate a bundle of amplified pulses (20) limited in energy by pulse; and
the optic gain medium (1) requires a propagation axis unique to the continuous laser bundle (11) and to the bundle of amplified laser pulses (20).

2. Optical amplifier system according to claim 1, also comprising a second optic means of separation (8) able to separate spatially such bundle of amplified pulses (20) and the continuous laser bundle (11), the optic gain medium (1) being arranged between the first optic means of separation (7, 14) and the second optic means of separation (8), so as to generate a bundle of amplified pulses (20) limited in energy following a first direction and to generate a continuous laser bundle (11) following another direction.

3. Optical amplifier system according to claim 1, in which such optic gain medium (1) comprises a fiber optic or a fiber optic rod, the trajectory of the continuous laser bundle and of the bundle of pulses being collinear in the gain medium (1), such fiber optic or such fiber optic rod having a bandwidth of amplification or a gain of amplification with a spectral width greater than or equal to 1 nm.

4. Amplifier system according to one of claim 1, in which the first optic means of separation (7, 14) and/or the second optic means of separation (8) comprise at least a dichroic filter able to separate the bundle of laser pulses at a wavelength λ₁ and the continuous laser bundle (11) at a wavelength λ₂.

5. Amplifier system according to claim 1, in which the second optic means of separation (8) comprise a polarization filter and/or in which such first optic means of separation (7, 14) comprise a polarization filter, such polarization filter being able to separate the bundle of laser pulses according to a first polarization and the continuous laser bundle (11) according to a second polarization distinct from the first polarization.

6. Optical amplifier system according to claim 1, in which the induced optic losses of the means of optic losses (9) are adjustable so as to adjust the threshold of the continuous resonating cavity (C2).

7. Laser triggered with high power, high energy and high speed pulses, with the triggered laser comprising:
a solid state optic gain medium (1) in a first resonating cavity (C1);
optic triggering means (4, 14) arranged in such first resonating cavity, so as to trigger the emission of a bundle of high speed laser pulses in such first resonating cavity (C1), with the rate of the laser pulses being between 1 kHz and several hundred kHz; and
means of limitation (9, M5, M6) of the energy stored by optic pumping in such optic gain medium (1);
characterized in that such laser comprises:
a second continuous resonating cavity (C2), the first resonating cavity (C1) and the second continuous resonating cavity (C2) having a common part comprising the optic gain medium (1) and the means of optic triggering (4), the first resonating cavity (C1) having at least a first branch separate from such common part, and the second resonating cavity (C2) having at least a second branch of losses separated from such common part, such second branch of losses comprising the means of optic losses (9) and
first optic means of separation (7, 14) being arranged in such first and second resonating cavity (C1, C2) so as to separate the common part respectively of the first branch and the second branch of losses, such first optic means of separation (7, 14) being able to direct a bundle of laser pulses toward the first branch of the first resonating cavity (C1) and to direct a continuous laser bundle toward the second branch of losses from the second continuous resonating cavity (C2).

8. Laser with triggered pulses according to claim 7 in which such means of optical triggering (4) comprises an acousto-optic modulator (polarizing or non polarizing) or an electro-optic modulator.

9. Laser with triggered pulses according to claim 7 in which such optic gain medium (1) comprises a fiber optic or a fiber optic rod, such fiber optic or such fiber optic rod (1) having a bandwidth of amplification and/or a gain of amplification of spectral width greater than or equal to 1 nm.

10. Laser with triggered pulses according to claim 7, in which the second optic means of separation (8) comprise a dichroic filter and/or in which such first optic means of separation (7, 14) comprise a dichroic filter, such dichroic filter being able to separate the bundle of laser pulses at a wavelength λ₁ and the continuous laser bundle at a wavelength λ₂.

11. Laser with triggered pulses according to claim 7, in which the second optic means of separation (8) comprise a polarization filter and/or in which such first optic means of separation (7, 14) comprise a polarization filter, such polarization filter being able to separate the bundle of laser pulses according to a first polarization and the continuous laser bundle according to a second polarization distinct from the first polarization.

12. Laser with triggered pulses according to claim 7, in which such means of loss are adjustable so as to adjust the threshold of the continuous resonating cavity.

13. Laser with triggered pulses according to claim 7 in which the second optic means of separation comprise a non-linear crystal able to produce an wave at a frequency different from the fundamental wave with a performance depending on the incident wavelength and/or of the incident polarization and/or of the incident peak power.

14. Laser with triggered pulses and optical amplifier using an energy limiter according to claim 7, characterized in that:
the system comprises two gain mediums separated by at least one optic component closing the first resonating cavity (C1) of the pulsed laser triggered, in which the continuous laser bundle produced by the second continuous resonating cavity (C2) traverses the second gain medium.

15. Process for high power, high energy and high speed laser (10) pulse amplification, with the process comprising the following stages:
Optic pumping of a solid state gain medium (1);
Generation of a bundle of laser pulses to be amplified (10) at a rate of between 1 kHz and several hundred kHz;
Addressing of the bundle of laser pulses to be amplified (10) in the direction of a solid state gain medium (1);
amplification of the bundle of laser pulses by single or double passage in the solid state gain medium (1) so as to generate a bundle of amplified laser pulses (20), with such process comprising a stage of limitation of energy stored. by optic pumping in such optic gain medium (1), characterized in that such limitation stage comprises the following stages:
formation of a continuous resonant cavity comprising such solid state gain medium (1) so as to generate a continuous laser bundle in such continuous resonant cavity (C2) when the gain of the gain medium (1) is greater than or equal to preset threshold equal to the optic losses and to generate a bundle of amplified pulses (20) limited in energy by pulse.
